(19) United States
(12) Patent Application Publication
(10) Pub. No.: US 2006/0156125 A1
(43) Pub. Date: Jul. 13, 2006

(54) Shift register system, method and driving circuit

(75) Inventors: Sz Hsiao Chen, Miao-Li (TW); Long Kuan Chen, Miao-Li (TW); Tsau Hua Hsieh, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/289,203

(22) Filed: Nov. 28, 2005

(30) Foreign Application Priority Data
Nov. 26, 2004 (TW) 93136460

(51) Int. Cl. G01R 31/28

(52) U.S. Cl. 714/729

(57) ABSTRACT

An exemplary shift register system (31) includes a shift register (311), and four switches (312-315). The shift register includes input pins, output pins, a start pin, a reset pin, a first controlling pin, and a second controlling pin. Each switch includes input pins according to the output pins of the shift register, output pins, an enabling pin, and a third controlling pin. The switches are connected with each other in series through respective of the enabling and controlling pins thereof. The enabling pin of the first switch is connected to the start pin of the shift register, and the third controlling pin of the last switch is connected to the reset pin of the shift register. The output pins of the shift register are connected to the input pins of each switch through a bus line (316), and the output pins of the switches are connected to an external circuit.

### FIELD OF THE INVENTION

The present invention relates to a shift register system, and more particularly to a shift register system typically used in a liquid crystal display (LCD).

### BACKGROUND

An LCD device has the advantages of portability, low power consumption, and low radiation, and has been widely used in various portable information products such as notebooks, personal digital assistants (PDAs), video cameras and the like. Furthermore, the LCD device is considered by many to have the potential to completely replace CRT (cathode ray tube) monitors and televisions.

FIG. 4 is essentially an abbreviated circuit diagram of a conventional active matrix LCD. The active matrix LCD 100 includes a first substrate (not shown), a second substrate (not shown) arranged in a position facing the first substrate, a liquid crystal layer (not shown) sandwiched between the first substrate and the second substrate, a data driving circuit 200, a gate driving circuit 300, and a timing control circuit 400.

The first substrate includes a number n (where n is a natural number) of gate lines 101 that are parallel to each other and that each extend along a first direction, and a number m (where m is also a natural number) of data lines 102 that are parallel to each other and that each extend along a second direction orthogonal to the first direction. The first substrate also includes a plurality of thin film transistors (TFTs) 106 that function as switching elements. The first substrate further includes a plurality of pixel electrodes 103 formed on a surface thereof facing the second substrate. Each TFT 106 is provided in the vicinity of a respective point of intersection of the gate lines 101 and the data lines 102.

Each TFT 106 includes a gate electrode, a source electrode, and a drain electrode. The gate electrode of each TFT 106 is connected to the corresponding gate line 101. The source electrode of each TFT 106 is connected to the corresponding data line 102. The drain electrode of each TFT 106 is connected to a corresponding pixel electrode 103.

The second substrate includes a plurality of common electrodes 105 opposite to the pixel electrodes 103. In particular, the common electrodes 105 are formed on a surface of the second substrate facing the first substrate, and are made from a transparent material such as ITO (Indium-Tin Oxide) or the like. A pixel electrode 103, a common electrode 105 facing the pixel electrode 103, and liquid crystal molecules of the liquid crystal layer sandwiched between the two electrodes 103, 105 cooperatively define a single pixel unit.

The gate driving circuit 300 includes a first shift register 310 for receiving scanning signals, a level shift 320 for transforming the scanning signals to a plurality of voltages, and a first output circuit 330 connected to the plurality of gate lines 101.

The data driving circuit 200 includes a second shift register 210 for receiving image signals, a sampler 220 for transforming the image signals to a plurality of voltages, and a second output circuit 230 connected to the plurality of data lines 102. The first and second shift registers 310, 210 used in the gate driving circuit 300 and the data driving circuit 200 are integrated circuits (ICs).

Because the first shift register 310 has a plurality of output pins for driving the plurality of gate lines 101, the first shift register 310 must have a same number of register units therewithin. In other words, the number of output pins of the shift register 310 must be the same as the number of register units inside the shift register 310. This means that different first shift registers 310 need to be manufactured for different kinds of active matrix LCDs 100 having different numbers of gate lines 101.

It is desired to provide a shift register system which overcomes the above-described deficiencies.

### SUMMARY

An exemplary shift register system comprises a shift register and a plurality of switches. The shift register includes a plurality of input pins, a plurality of output pins, a start pin, a reset pin, a first controlling pin, and a second controlling pin. Each switch includes a plurality of input pins corresponding to the output pins of the shift register, a plurality of output pins, an enabling pin, and a third controlling pin. The switches are connected with each other in series through the enabling pins and the controlling pins. The enabling pin of the first switch is connected to the start pin of the shift register, the third controlling pin of the last switch is connected to the reset pin of the shift register, the output pins of the shift register are connected to the input pins of each switch through a bus line, and the output pins of the switches are connected to an external circuit.

In an exemplary method for driving a shift register system, the shift register system comprises a number m (m≧1) of switches, and a shift register having a number n (n≧1) of output pins. The method comprises the following steps: triggering the shift register and a switch j (1≦j≦m) to be in on state by an external start signal; transmitting a plurality of shift signals from the output pins of the shift register to the switch j when the switch j is in the on state; providing the plurality of shift signals to an external circuit when the switch j is in the on state; triggering a switch j+1 to be in on state, by the switch j when the switch j has finished providing the plurality of shift signals to the external circuit; transmitting a plurality of shift signals from the output pins of the shift register to the switch j+1 when the switch j+1 is in the on state; and providing the plurality of shift signals to the external circuit when the switch j+1 is in the on state.

An exemplary circuit for driving a liquid crystal display comprises a plurality of gate lines that are parallel to each other and that each extend along a first direction, a plurality of data lines that are parallel to each other and that each extend along a second direction orthogonal to the first direction, a plurality of thin film transistors provided in the vicinity of respective points of intersection of the gate lines and the data lines, a data driving circuit connected to the plurality of gate lines, and a gate driving circuit connected to the plurality of gate lines. The gate driving circuit comprises a shift register system. The shift register system comprises a shift register and a plurality of switches. The shift register includes a plurality of input pins, a plurality of output pins, a start pin, a reset pin, a first controlling pin, and a second controlling pin. Each switch includes a plurality of input pins corresponding to the output pins of the shift register, a plurality of output pins, an enabling pin, and a third controlling pin. The switches are connected with each other in series through respective of the enabling pins and the controlling pins thereof. The enabling pin of the first switch is connected to the start pin of the shift register, and the third controlling pin of the last switch is connected to the reset pin of the shift register. The output pins of the shift register are connected to the input pins of each switch through a bus line, and the output pins of the switches are connected to an external circuit.

Unlike in the conventional shift register used in the above-described conventional gate driving circuit, the present shift register system may have a reduced or expanded number of output pins according to a selected quantity of switches used therein.

Other advantages and novel features will become more apparent from the following detailed description when taken in conjunction with the accompanying drawings, in which:

### BRIEF DESCRIPTION OF THE DRAWINGS

FIG. 1 is an abbreviated circuit diagram of a shift register system in accordance with an exemplary embodiment of the present invention;

FIG. 2 is an abbreviated timing chart of signals transmitted in the shift register system of FIG. 1;

FIG. 3 is essentially an abbreviated circuit diagram of an exemplary liquid crystal display using the shift register system of FIG. 1; and

FIG. 4 is essentially an abbreviated circuit diagram of a conventional active matrix LCD.

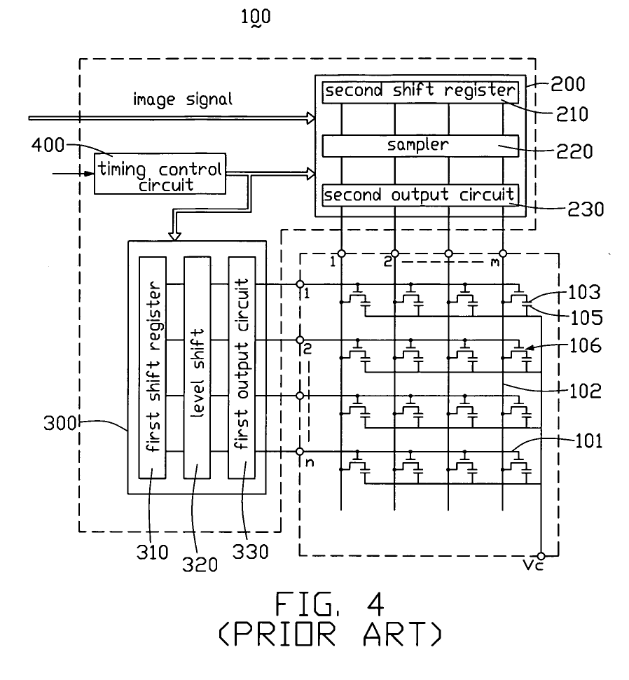

### DETAILED DESCRIPTION OF EMBODIMENTS

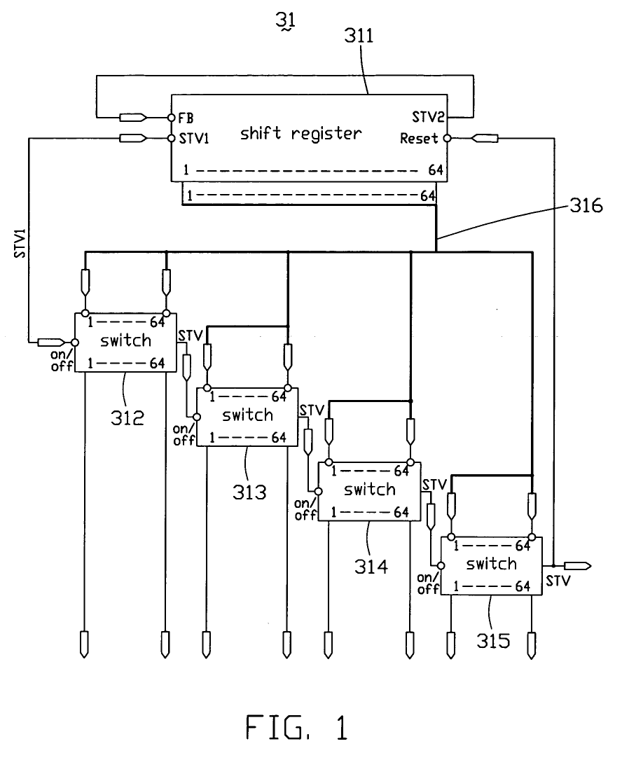

FIG. 1 is an abbreviated circuit diagram of a shift register system in accordance with an exemplary embodiment of the present invention. The shift register system 31 includes a shift register 311, a first switch 312, a second switch 313, a third switch 314, and a fourth switch 315.

The shift register 311 includes sixty-four register units (not shown) integrated therein, sixty-four output pins, a start pin STV1, a reset pin Reset, a first controlling pin FB, and a second controlling pin STV2.

Each of the switches 312, 313, 314, 315 includes sixty-four input pins that are connected to the output pins of the shift register 311 through a bus line 316, sixty-four output pins, an enabling pin on/off, and a third controlling pin STV.

The switches 312, 313, 314, 315 are connected with each other in series through the respective enabling pins on/off and the respective third controlling pins STV. The enabling pin on/off of the first switch 312 is connected to the start pin STV1 of the shift register 311. The controlling pin STV of the fourth switch 315 is connected to the reset pin of the shift register 311. The output pins of the shift register 311 are connected to the input pins of the switches 312, 313, 314, 315 by a 64-bit data bus line 316. The output pins of the switches 312, 313, 314, 315 are connected to a second external circuit (not shown). Accordingly, the shift register system 31 has 256 output pins. The shift register system 31 may have an expanded number of output pins according to a desired quantity of switches used therein.

A method for driving the shift register system 31 includes the following steps: triggering the shift register 311 and a switch j (311≦j≦314) to be in on state by an external start signal received from a first external circuit; transmitting a plurality of shift signals from the output pins of the shift register 311 to the switch j when the switch j is in the on state; providing the plurality of shift signals to the second external circuit when the switch j is in on state; triggering a switch j+1 to be in on state, by the switch j when the switch j has finished providing the plurality of shift signals to the second external circuit; transmitting a plurality of shift signals from the output pins of the shift register 311 to the switch j+1 when the switch j+1 is in on state; and providing the plurality of shift signals to the second external circuit when the switch j+1is in the on state.

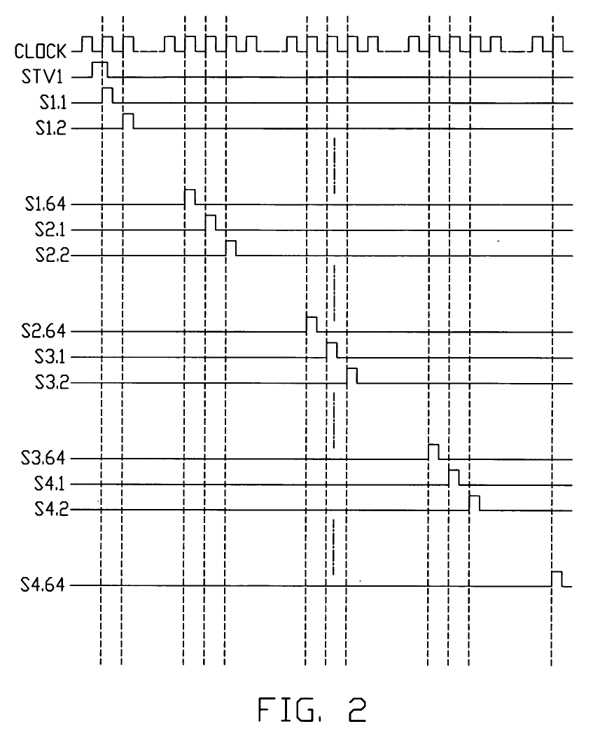

FIG. 2 is an abbreviated timing chart of signals transmitted in the shift register system 31. In operation, the enabling pin on/off of the first switch 312 and the start pin STV1 of the shift register 311 synchronously receive a start pulse signal from the first external circuit (not shown). When the shift register 311 receives the start pulse signal, it generates a plurality of shift signals and provides the shift signals to the sixty-four output pins thereof. Because the first switch 312 is already turned on by reason of the enabling pin on/off thereof receiving the start pulse signal, the first switch 312 receives the shift signals provided by the shift register 311 and outputs the shift signals from the sixty-four output pins thereof. The shift signals outputted by the first switch 312 are shown as S1.1-S1.64 in FIG. 2. At the same time, the other switches 313, 314, 315 are in an off state.

After sixty-three clock periods, the third controlling pin STV of the first switch 312 applies a control signal to turn on the second switch 313 and turn itself off. At the same time, the second controlling pin STV2 of the shift register 311 sends a pulse to the first controlling pin FB of the shift register 311. Then the shift register 311 provides a plurality of shift signals to the sixty-four output pins thereof. Because the second switch 313 is already turned on by reason of the enabling pin on/off thereof receiving the control signal, the second switch 313 receives the shift signals provided by the shift register 311 and outputs the shift signals from the sixty-four output pins thereof. The shift signals outputted by the second switch 313 are shown as S2.1-S2.64 in FIG. 2. At the same time, the other switches 312, 314, 315 are in an off state.

After sixty-three clock periods again, the third controlling pin STV of the second switch 313 applies a control signal to turn on the third switch 314 and turn itself off. At the same time, the second controlling pin STV2 of the shift register 311 sends a pulse to the first controlling pin FB of the shift register 311. Then the shift register 311 provides a plurality of shift signals to the sixty-four output pins thereof. Because the third switch 314 is already turned on by reason of the enabling pin on/off thereof receiving the control signal, the third switch 314 receives the shift signals provided by the shift register 311 and outputs the shift signals from the sixty-four output pins thereof. The shift signals outputted by the third switch 314 are shown as S3.1-S3.64 in FIG. 2. At the same time, the other switches 312, 313, 315 are in an off state.

After sixty-three clock periods again, the third controlling pin STV of the third switch 314 applies a control signal to turn on the fourth switch 315 and turn itself off. At the same time, the second controlling pin STV2 of the shift register 311 sends a pulse to the controlling pin FB of the shift register 311. Then the shift register 311 provides a plurality of shift signals to the sixty-four output pins thereof. Because the fourth switch 315 is already turned on by reason of the enabling pin on/off thereof receivign the control signal, the fourth switch 315 receives the shift signals provided by the shift register 311 and outputs the shift signals from the sixty-four output pins thereof. The shift signals outputted by the fourth switch 315 are shown as S4.1-S4.64 in FIG. 2. At the same time, the other switches 312, 313, 314 are in an off state.

After the fourth switch 315 has outputted the shift signals from the sixty-four output pins thereof, the fourth switch 315 turns off itself. At the same time, the fourth switch 315 sends a pulse signal from the third controlling pin STV thereof to the Reset pin of the shift register 311. After the shift register 311 receives the pulse signal, it stops outputting the shift signals.

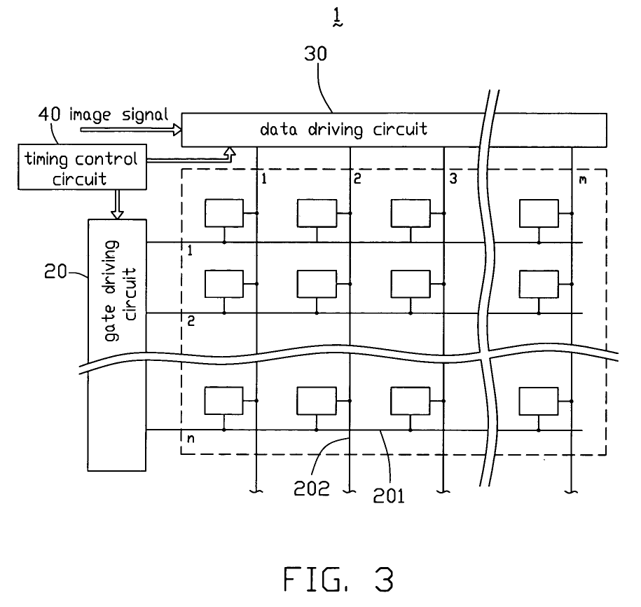

FIG. 3 is essentially an abbreviated circuit diagram of an exemplary liquid crystal display using the shift register system 31. The liquid crystal display 1 includes a first and a second substrates (not shown), a liquid crystal layer (not shown) sandwiched between the first and second substrates, a gate driving circuit 20, a data driving circuit 30, and a timing control circuit 40. The first substrate includes a number n (where n is a natural number) of gate lines 201 that are parallel to each other and that each extend along a first direction, and a number m (where m is also a natural number) of data lines 202 that are parallel to each other and that each extend along a second direction orthogonal to the first direction. The first substrate also includes a plurality of thin film transistors (not shown) that function as switching elements. Each TFT is provided in the vicinity of a respective point of intersection of the gate lines 201 and the data lines 202.

The gate driving circuit 20 includes a shift register (not shown), a level shift (not shown) for transforming the scanning signals to a plurality of voltages, and an output circuit (not shown) connected to the plurality of gate lines. The level shift has a same configuration as that of the shift register 311.

The data driving circuit 30 mainly includes a shift register (not shown) for receiving image signals, a sampler (not shown) for transforming the image signals to a plurality of voltages, and an output circuit (not shown) connected to the plurality of data lines 202.

The above-described exemplary shift register system 31 has 256 output pins. Unlike in the conventional shift register used in the above-described conventional gate driving circuit 300, the shift register system 31 may have a reduced or expanded number of output pins according to a selected quantity of switches used therein.

It is to be understood, however, that even though numerous characteristics and advantages of the exemplary embodiments have been set out in the foregoing description, together with details of the structures and functions of the embodiments, the disclosure is illustrative only; and that changes may be made in detail, especially in matters of shape, size, and arrangement of parts within the principles of the invention to the full extent indicated by the broad general meaning of the terms in which the appended claims are expressed.

What is claimed is:

1. A shift register system comprising:
a shift register including a plurality of input pins for receiving signals from a first external circuit, a plurality of output pins, a start pin, a reset pin, a first controlling pin, and a second controlling pin, and
a plurality of switches, each of the switches including a plurality of input pins according to the plurality of output pins of the shift register, a plurality of output pins, an enabling pin, and a third controlling pin;
wherein the switches are connected with each other in series through respective of the enabling pins and controlling pins, the enabling pin of a first one of the switches being connected to the start pin of the shift register, the third controlling pin of a last one of the switches being connected to the reset pin of the shift register, the output pins of the shift register being connected to the input pins of each switch through a bus line, and the output pins of the switches being connected to a second external circuit.

2. The shift register system as claimed in claim 1, wherein the number of output pins of the shift register is sixty-four.

3. The shift register system as claimed in claim 1, wherein the number of switches is four.

4. A method for driving a shift register system, the shift register system comprising a number m (m≧1) of switches and a shift register having a number n (n≦1) of output pins, the method comprising the following steps:
triggering the shift register and a switch j (1≦j≦m) to be in on state by an external start signal;
transmitting a plurality of shift signals from the output pins of the shift register to the switch j when the switch j is in the on state;
providing the shift signals to an external circuit when the switch j is in the on state;
triggering a switch j+1 to be in on state, by the switch j when the switch j has finished providing the shift signals to the external circuit;
transmitting a plurality of shift signals from the output pins of the shift register to the switch j+1 when the switch j+1 is in the on state; and
providing the shift signals to the external circuit when the switch j+1 is in the on state.

5. The method for driving a shift register system as claimed in claim 4, wherein m is equal to four.

6. The method for driving a shift register system as claimed in claim 4, wherein n is equal to sixty-four.

7. A circuit for driving a liquid crystal display, comprising:
a plurality of gate lines that are parallel to each other and that each extend along a first direction;
a plurality of data lines that are parallel to each other and that each extend along a second direction orthogonal to the first direction;
a plurality of thin film transistors provided in the vicinity of respective points of intersection of the gate lines and the data lines;
a data driving circuit connected to the plurality of gate lines; and
a gate driving circuit connected to the plurality of gate lines, the gate driving circuit comprising a shift register system, the shift register system comprising:
a shift register including a plurality of input pins for receiving signals from a first external circuit, a plurality of output pins, a start pin, a reset pin, a first controlling pin, and a second controlling pin; and
a plurality of switches, each of the switches including a plurality of input pins according to the plurality of output pins of the shift register, a plurality of output pins, an enabling pin, and a third controlling pin;
wherein the switches are connected with each other in series through respective of the enabling pins and controlling pins, the enabling pin of a first one of the switches being connected to the start pin of the shift register, the third controlling pin of a last one of the switches being connected to the reset pin of the shift register, the output pins of the shift register being connected to the input pins of each switch through a bus line, and the output pins of the switches being connected to a second external circuit.

8. The circuit for driving a liquid crystal display as claimed in claim 7, wherein the number of output pins of the shift register is sixty-four.

9. The circuit for driving a liquid crystal display as claimed in claim 7, wherein the number of switches is four.
